(19) United States
(12) Patent Application Publication
(10) Pub. No.: US 2011/0259387 A1
(43) Pub. Date: Oct. 27, 2011

(54) MULTI-JUNCTION SOLAR CELL STRUCTURE

(75) Inventors: Chan Shin WU, Hukou Shiang (TW); Tsung-Pei CHIN, Hukou Shiang (TW); Yung-Yi TU, Hukou Shiang (TW)

(73) Assignee: SOLAPOINT CORPORATION, Hukou Shiang (TW)

(21) Appl. No.: 13/092,122

(22) Filed: Apr. 21, 2011

(30) Foreign Application Priority Data
Apr. 23, 2010 (TW) 099112828

(51) Int. Cl. H01L 31/042; H01L 31/18; H01L 31/06

(52) U.S. Cl. 136/244; 136/255; 438/74; 257/E31.054

(57) ABSTRACT

A multi-junction solar cell structure includes a supporting substrate, a Group IV element-based thin film, and a Group III-V element-based thin film sequentially stacked on the supporting substrate. When the multi-junction solar cell structure is active, the Group III-V element-based thin film contacts the light before the Group IV element-based thin film does. The Group IV element-based thin film includes a first solar cell and the Group III-V element-based thin film includes a second solar cell, wherein the band gap of the first solar cell is lower than the band gap of the second solar cell.

### RELATED APPLICATIONS

This application claims the right of priority based on Taiwan Patent Application No. 99112828, entitled “MULTI-JUNCTION SOLAR CELL STRUCTURE”, filed on Apr. 23, 2010. The entire content of the aforementioned application is incorporated herein by reference.

### FIELD OF THE INVENTION

The present invention relates to a solar cell structure, and more particularly, to a solar cell structure having multiple junctions.

### BACKGROUND OF THE INVENTION

In recent years, solar energy has become an important new type of energy source. Research on the development of solar energy is tremendously conducted on a global scale. Hitherto, numerous solar cells of different forms have been commercialized to enable mass production thereof and have become consumer products. Hence, ongoing improvement on solar cell technology is urgently required to meet the future need for the development of solar energy.

Based on existing known technologies, a new approach combining material growth and processing is proposed to fabricate high-concentration photovoltaic (HCPV) multiple junction devices. Multiple junction structure typically consists of 3-junction (3J), but studies of as high as 6-junction have been reported. Currently, the 3-junction solar cell structure includes at least two types. The first type includes 3 junctions by sequentially depositing Ge, GaAs, and InGaP on Ge substrate, which contributes the photoelectric conversion efficiency around 39%. The second type includes 3 junctions by sequentially depositing InGaAs, GaAs, and InGaP on GaAs substrate, characterized in having an inverted metamorphic (IMM) buffer layer. The second type holds the photoelectric conversion efficiency more than 41%. However, the growth of highly mismatched, fully relaxed and high quality IMM buffer layer is difficult and less well controlled. The growth time is significantly longer and thus production throughput is reduced. Furthermore, the highly dislocated IMM buffer layer is required with a significant thickness. This will result in undesired high resistance with increased junction temperature, which may adversely cause a reliability concern.

The prior art provides plenty of structures and methods that are similar to the above and thus, inevitably, has various drawbacks. Therefore, it is imperative that the prior art should be supplemented with novel ideas that have inventiveness over the prior art.

### SUMMARY OF THE INVENTION

Accordingly, the present invention has been made keeping in mind the above problems occurring in the prior art, and one aspect of the present invention is to provide a peeling layer on the growth substrate, to grow multiple solar cells sequentially on the growth substrate from the higher band gap to the lower band gap, to provide a supporting substrate to connect the multiple solar cells from the top, and to remove the peeling layer so that the growth substrate is detached from the bottom.

Another aspect of the present invention is that the growth substrate is reusable.

A further aspect of the present invention is that the multiple solar cells are sequentially arranged on the supporting substrate from the lower band gap to the higher band gap, so that the solar cell having lower band gap is located on the bottom serving as the last layer for receiving light. The material of the solar cell having lower band gap is selected from the Group IV elements in the period table. The material of the solar cell having higher band gap can be selected from the Group III-V elements in the period table. In comparison with the second type solar cell, the present invention does not require the IMM buffer layer, thus reducing the heat resistance.

Another aspect of the present invention is that the solar cell having the lowest band gap from the multiple solar cells is a Ge junction.

A further another aspect of the present invention is that the material of the Ge junction contains small amount of Si.

A yet another aspect of the present invention is that an ohmic contact layer is grown on the Ge junction. The doping concentration of the ohmic contact layer is higher than the doping concentration of the Ge junction to reduce resistance.

In one aspect, the present invention provides a multi-junction solar cell structure including: a supporting substrate; a Group IV element-based thin film on the supporting substrate, the Group IV element-based thin film having a first solar cell; and a Group III-V element-based thin film on the Group IV element-based thin film, wherein the Group III-V element-based thin film is determined to contact the light before the Group IV element-based thin film does, the Group III-V element-based thin film having a second solar cell, and wherein the band gap of the first solar cell is lower than the band gap of the second solar cell.

In another aspect, the present invention provides a method of forming a multi-junction solar cell structure including: providing a growth substrate; growing a peeling layer on the growth substrate; growing a Group III-V element-based thin film on the peeling layer, the Group III-V element-based thin film having a second solar cell; growing a Group IV element-based thin film on Group III-V element-based thin film, the Group IV element-based thin film having a first solar cell, wherein the band gap of the first solar cell is lower than the band gap of the second solar cell, and the Group III-V element-based thin film is determined to contact the light before the Group IV element-based thin film does; providing a supporting substrate to connect the Group IV element-based thin film and the Group III-V element-based thin film from the direction approaching the Group IV element-based thin film; and removing the peeling layer to detach the growth substrate and expose the Group III-V element-based thin film.

Other aspects of the present invention solve other problems and are disclosed and illustrated in detail with the embodiments below together with the aforesaid aspects.

### BRIEF DESCRIPTION OF THE PICTURES

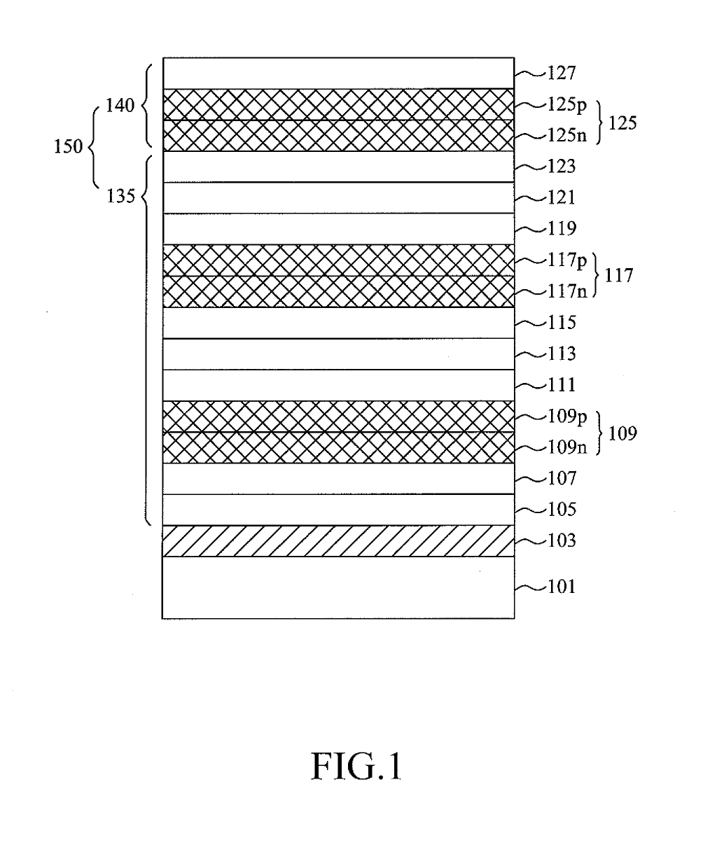

FIG. 1 through FIG. 4 are cross-sectional views of a manufacturing process of a solar cell structure in accordance with one preferred embodiment of the present invention.

### DETAILED DESCRIPTION OF THE INVENTION

The preferred embodiments of the present invention will now be described in greater details by referring to the drawings that accompany the present application. It should be noted that the features illustrated in the drawings are not necessarily drawn to scale. Descriptions of well-known components, materials, and process techniques are omitted so as to not unnecessarily obscure the embodiments of the invention.

FIG. 1 through FIG. 4 are cross-sectional views of a manufacturing process of a multi-junction solar cell structure 400 in accordance with one preferred embodiment of the present invention. The solar cell structure of the present invention can include “at least two” solar cells, wherein the term “at least two” means two, three, four, five, six, or more. In this embodiment, for example, the number of solar cell is three, but not limited thereto. Referring to FIG. 1, the method of forming three solar cells includes, firstly, providing a growth substrate 101. In this embodiment, the growth substrate 101 is a GaAs substrate; however, in other embodiments, the growth substrate 101 can be a Ge substrate or other substrates having suitable lattice constant. The growth substrate 101 is a primary substrate for growing the solar cell thin film and should have a suitable thickness for supporting the layers to be grown. In this embodiment, the thickness of the growth substrate 101 is approximately between 150 μm and 200 μm.

Referring to FIG. 1, after providing the growth substrate 101, various layers are sequentially epitaxially grown. The term “epitaxially grow(n)” or “grow(n)” includes Metal Organic Chemical Vapor Deposition (MOCVD) or other suitable techniques. A peeling layer 103 is firstly grown. The peeling layer 103 serves to temporarily connect the growth substrate 101 and the subsequent layers grown thereon. The material of the peeling layer 103 can be AlAs, InGaP, InAlP, InAlGaP, AlGaAs, etc. In this embodiment, the material of the peeling layer 103 is AlGaAs or AlAs.

Then, a Group III-V element-based thin film 135 is grown on the peeling layer 103, wherein the Group III-V element-based thin film 135 includes layers 105 to 123 that contain various elements from Group III-V in the period table. Also referring to FIG. 1, the step of growing the Group III-V element-based thin film 135 includes growing a cover layer 105 and a first window layer 107. In this embodiment, the material of the cover layer 105 can be n-GaAs or n-InGaAs, wherein In is about 1 mole %. The material of the window layer 107 can be n-AlInP. Next, a high-band-gap solar cell 109 is grown on the window layer 107. The high-band-gap solar cell 109 includes an emitter layer 109n and a base layer 109p, wherein the material thereof can be InGaP or AlInGaP in this embodiment. Then, a first back field layer 111 is optionally grown on the high-band-gap solar cell 109. In this embodiment, the material of the first back field layer 111 is p-AlInP. Subsequently, a first tunnel junction 113 is grown on the first back field layer 111 to electrically connect the mid-band-gap solar cell 117 later grown. In this embodiment, the material of the first tunnel junction 113 is a combination of heavily doped p++AlGaAs and n++InGaP.

Also referring to FIG. 1, a second window layer 115 is grown on the first tunnel junction 113. In this embodiment, the material of the second window layer 115 can be n-AlInP. Then, a mid-band-gap solar cell 117 is grown on the second window layer 115. The mid-band-gap solar cell 117 includes an emitter layer 117n and a base layer 117p, wherein in this embodiment, the material thereof can be GaAs or InGaAs containing less In. Next, a second back field layer 119 is optionally grown on the mid-band-gap solar cell 117. In this embodiment, the material of the second back field layer 119 can be p-InGaP. A second tunnel junction 121 is subsequently grown on the second back filed layer 119 to electrically connect the low-band-gap solar cell 125. In this embodiment, the material of the second tunnel junction 121 can be a combination of heavily doped p++GaAs and n++GaAs.

Also Referring to FIG. 1, a third window layer 123 is grown on the second tunnel junction 121. In this embodiment, the material of the third window layer 123 can be n-InGaAs. The layers 105 to 123 described above form the Group III-V element-based thin film 135. The material of layers 105 to 123 can be selected from the elements of Group III-V in the period table based on the required lattice constant or band gap, or the function of respective layer. The materials used in the embodiment are only illustrative and not in a limited sense. In other embodiments, the Group III-V element-based thin film 135 can optionally include layers 105 to 123 described above as well as other suitable device layers.

Also referring to FIG. 1, a Group IV element-based thin film 140 is grown on the Group III-V element-based thin film 135. The Group IV element-based thin film 140 has a low-band-gap solar cell 125. In this embodiment, the low-band-gap solar cell 125 is grown on the third window layer 123. The low-band-gap solar cell 125 includes an emitter layer 125n and a base layer 125p. The growth of the low-band-gap solar cell 125 mainly utilizes elements from the Group IV in the period table and suitable dopants. In this embodiment, in consideration of matching lattice constant with the n-InGaAs of the third window layer 123, the low-band-gap solar cell 125 utilizes a layer of Ge or Ge containing less Si: SiₓGe₍₁₋ₓ₎, wherein 0<x<1. The term “containing less Si” means the amount of Si is less than Ge. The low-band-gap solar cell 125 is the lowest-band-gap junction in this embodiment. Then, an ohmic contact layer 127 is grown on the low-band-gap solar cell 125. The material of the ohmic contact layer 127 can be similar to that of the low-band-gap solar cell 125. However, In order to reduce resistance, the doping concentration of the ohmic contact layer 127 is higher than the doping concentration of the low-band-gap solar cell 125. In this embodiment, the Group IV element-based thin film 140 includes the low-band-gap solar cell 125 and the ohmic contact layer 127, wherein the material of layer 125 or 127 can be selected from the elements of Group IV in the period table based on the required lattice constant or band gap, or the function of respective layer. The materials used in the embodiment are only illustrative and not in a limited sense. In other embodiments, the Group IV element-based thin film 140 can optionally include the layer 125 or 127 described above as well as other suitable device layers.

The thin film 150 consisting of the Group IV element-based thin film 140 and the Group III-V element-based thin film 135 form the main structure of the solar cell structure 100 of this embodiment. The thickness of the combined thin film 150 is approximately between 25 μm and 35 μm in this embodiment.

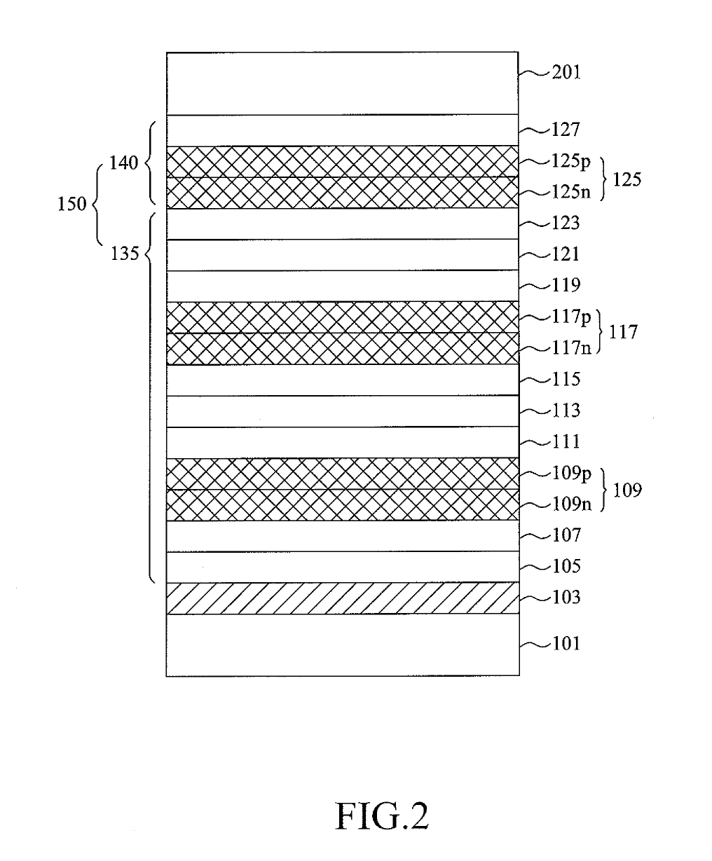

Then, referring to FIG. 2, a supporting substrate 201 is connected to the ohmic contact layer 127. The supporting substrate 201 is configured to replace the growth substrate 101 and support the combined thin film 150. The supporting substrate 201 can be a solar dissipation substrate in the final product or a temporary substrate not in the final product. In this embodiment, a silicon substrate is used as the supporting substrate 201, and the thickness thereof can be identical to the growth substrate 101 for operation convenience. In other embodiments, other materials can be utilized and other thicknesses may be applicable. An adhesive layer (not shown) can be optionally formed between the supporting substrate 20 and the ohmic contact layer 127, wherein the material and function of the adhesive layer can be similar to those of the peeling layer 103.

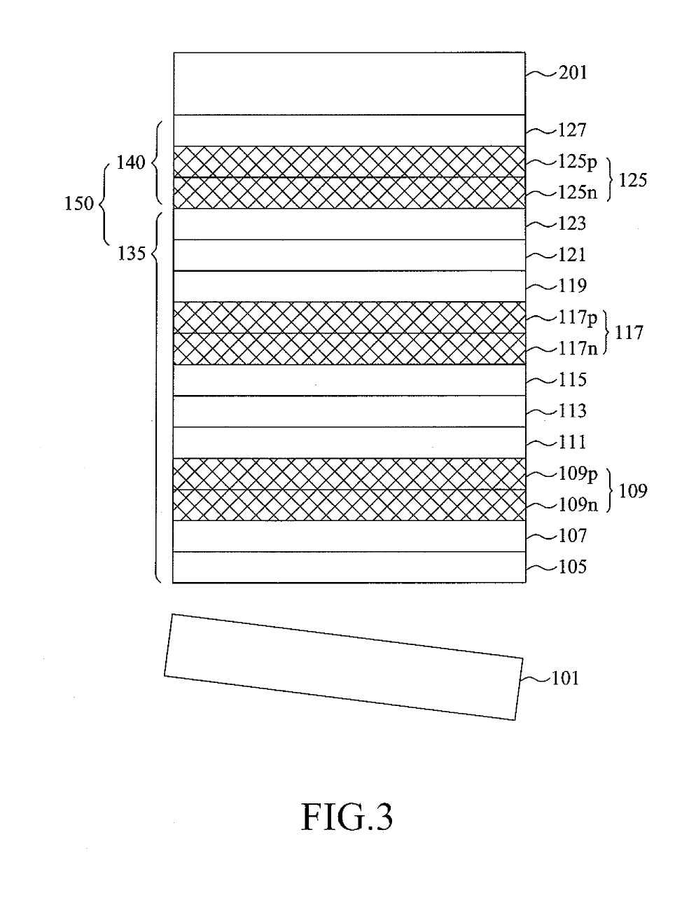

Referring to FIG. 3, after the connection of the supporting substrate 201 and the ohmic contact layer 127 is completed, the peeling layer 103 is removed to detach the growth substrate 101. The method of removing the peeling layer 103 can include dipping the growth substrate 101 and the peeling layer 103 in a suitable solution, wherein the solution can be deionized water, a solution of hydrogen fluoride or hydrogen peroxide. Since the peeling layer 103 is dissolved in the solution, the growth substrate 101 can be separated from the supporting substrate 201 and the combined thin film 150. The detached growth substrate 101 can be reused in other suitable processes.

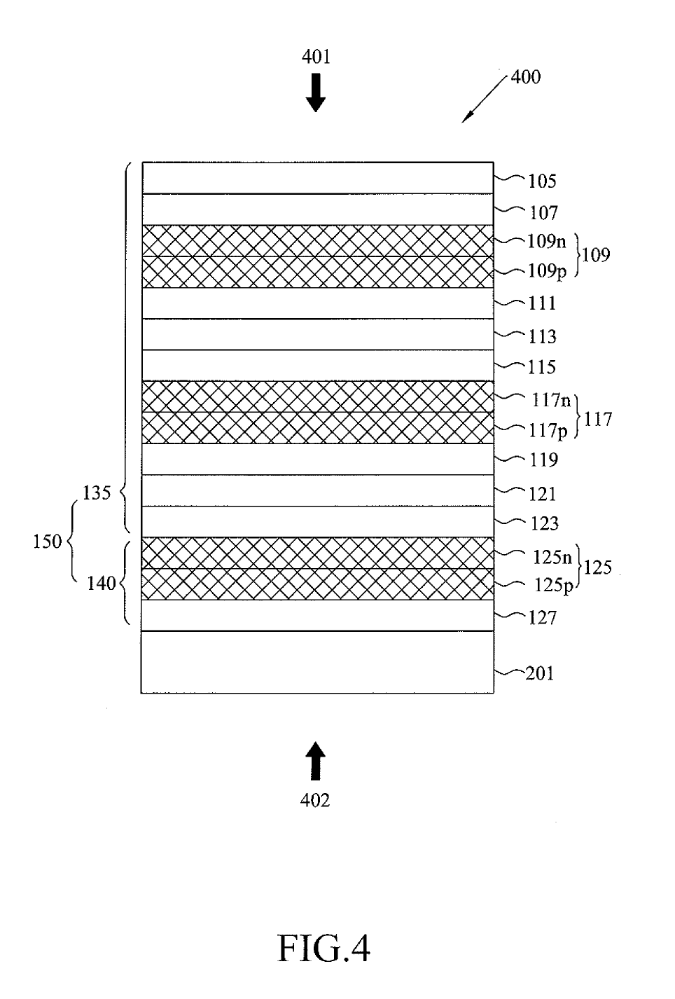

Referring to FIG. 4, after the detachment of the growth substrate 101, the entire structure is flipped over so that the supporting substrate 201 faces downward. FIG. 4 illustrates the multi-junction solar cell structure 400 of the embodiment. As shown in FIG. 4, the exposed face of the supporting substrate 201 which faces downward is the back side 402. Correspondingly, the exposed face of the topmost cover layer 105 is the front side 401. The front side 401 is a light receiving side. When the solar cell structure 400 is active, light comes in from this side, so that the Group III-V element-based thin film contacts the light before the Group IV element-based thin film does. The solar cells 125, 117, and 109 of the solar cell structure 400 are sequentially arranged on the supporting substrate 201 toward the light receiving side (i.e. the front side 401) from the low band gap to the high band gap. This embodiment may include other subsequent processes such as contact processes on the back side and the front side that can be referred to co-assigned Taiwan Patent Application No. 98124968, which is incorporated herein for reference by its entirety.

The foregoing preferred embodiments are provided to illustrate and disclose the technical features of the present invention, and are not intended to be restrictive of the scope of the present invention. Hence, all equivalent variations or modifications made to the foregoing embodiments without departing from the spirit embodied in the disclosure of the present invention should fall within the scope of the present invention as set forth in the appended claims.

1. A multi-junction solar cell structure, comprising:
a supporting substrate;
a Group IV element-based thin film on the supporting substrate, the Group IV element-based thin film having a first solar cell;
a Group III-V element-based thin film on the Group IV element-based thin film, wherein the Group III-V element-based thin film is determined to contact the light before the Group IV element-based thin film does, the Group III-V element-based thin film having a second solar cell,
wherein the band gap of the first solar cell is lower than the band gap of the second solar cell.

2. The multi-junction solar cell structure of claim 1, wherein the Group IV element-based thin film and the Group III-V element-based thin film are epitaxially grown from a growth substrate, and the growth substrate is not the supporting substrate.

3. The multi-junction solar cell structure of claim 1, wherein the Group III-V element-based thin film further comprises a third solar cell, the band gap of the first solar cell is lower than the band gap of the third solar cell.

4. The multi-junction solar cell structure of claim 3, further comprising a further solar cell in addition to the first solar cell, the second solar cell, and the third solar cell.

5. The multi-junction solar cell structure of claim 1, wherein the material of the Group III-V element-based thin film is selected from the group consisting of GaAs, InGaAs, InGaP, AlInGaP, AlInP, and AlGaAs.

6. The multi-junction solar cell structure of claim 1, wherein the material of the Group IV element-based thin film is selected from the group consisting of Ge or SiGe containing less Si than Ge.

7. The multi-junction solar cell structure of claim 1, wherein the Group IV element-based thin film further comprises an ohmic contact layer, the doping concentration of the ohmic contact layer is higher than the doping concentration of the first solar cell.

8. A method of forming a multi-junction solar cell structure, comprising:
providing a growth substrate;
growing a peeling layer on the growth substrate;
growing a Group III-V element-based thin film on the peeling layer, the Group III-V element-based thin film having a second solar cell;
growing a Group IV element-based thin film on Group III-V element-based thin film, the Group IV element-based thin film having a first solar cell,
wherein the band gap of the first solar cell is lower than the band gap of the second solar cell, and the Group III-V element-based thin film is determined to contact the light before the Group IV element-based thin film does;
providing a supporting substrate to support the Group IV element-based thin film and the Group III-V element-based thin film; and
removing the peeling layer to detach the growth substrate.

9. The method of claim 8, wherein the step of growing the Group III-V element-based thin film further comprises: growing a third solar cell, the band gap of the first solar cell is lower than the band gap of the third solar cell.

10. The method of claim 9, wherein the step of growing the Group III-V element-based thin film further comprises: growing a further solar cell in addition to the second solar cell and the third solar cell.

11. The method of claim 8, wherein the material of the Group III-V element-based thin film is selected from the group consisting of GaAs, InGaAs, InGaP, AlInGaP, AlInP, and AlGaAs.

12. The method of claim 8, wherein the material of the Group IV element-based thin film is selected from the group consisting of Ge or SiGe containing less Si than Ge.

13. The method of claim 1, wherein the step of growing the Group IV element-based thin film further comprises: growing an ohmic contact layer, the doping concentration of the ohmic contact layer is higher than the doping concentration of the first solar cell.
